(19) United States
(12) Patent Application Publication
(10) Pub. No.: US 2025/0140617 A1
(43) Pub. Date: May 1, 2025

(54) SEMICONDUCTOR SYSTEM AND METHOD FOR MANUFACTURING AND OPERATING THEREOF

(71) Applicant: INNOSCIENCE (SUZHOU) SEMICONDUCTOR CO., LTD., Jiangsu (CN)

(72) Inventors: Shan YIN, Guangdong (CN); Shoudong JIN, Guangdong (CN); Yiming LIN, Guangdong (CN); Xiong XIN, Guangdong (CN); King-Yuen WONG, Guangdong (CN)

(73) Assignee: INNOSCIENCE (SUZHOU) SEMICONDUCTOR CO., LTD., Jiangsu (CN)

(21) Appl. No.: 18/681,856

(22) PCT Filed: Sep. 30, 2022
(86) PCT No.: PCT/CN2022/123117

§ 371 Date: Feb. 6, 2024

(51) Int. Cl. H01L 21/66; H01L 21/67

(52) U.S. Cl. CPC H01L 22/14; H01L 21/67288

(57) ABSTRACT

A semiconductor system and its manufacturing and operating method are disclosed. The semiconductor system includes a clamping circuit, a first filter, a second filter, a first operational amplifier (OP) and a second OP. The clamping circuit is connected to a first terminal of a semiconductor device] to prevent the semiconductor device from interference. The first filter is connected to the clamping circuit. The first OP is connected to the first filter. The first OP is configured as a differential OP to generate a first output voltage, so that a voltage drop across a measurement resistor is excluded and an on-state voltage drop across the semiconductor device is measured. The second filter is connected to a second terminal of the semiconductor device. The second OP is connected to the second filter.

### BACKGROUND

### 1. Technical Field

The present disclosure relates to a semiconductor system and its manufacturing and operating method, and more particularly to a semiconductor system and its manufacturing and operating method for measuring the on-resistance.

### 2. Description of the Related Art

Components including direct bandgap semiconductors, for example, semiconductor components including group III-V materials or group III-V compounds (Category: III-V compounds) can operate or work under a variety of conditions or in a variety of environments (e.g., at different voltages and frequencies) due to their characteristics.

The semiconductor components may include a heterojunction bipolar transistor (HBT), a heterojunction field effect transistor (HFET), a high-electron-mobility transistor (HEMT), a modulation-doped FET (MODFET) and the like.

### SUMMARY

In some embodiments of the present disclosure, a semiconductor system is provided. The semiconductor system includes a clamping circuit, a first filter, a second filter, a first operational amplifier (OP) and a second OP. The clamping circuit is connected to a first terminal of a semiconductor device to prevent the semiconductor device from interference. The first filter is connected to the clamping circuit. The first OP is connected to the first filter. The first OP is configured as a differential OP to generate a first output voltage, so that a voltage drop across a measurement resistor is excluded and an on-state voltage drop across the semiconductor device is measured. The second filter is connected to a second terminal of the semiconductor device. The second OP is connected to the second filter. The second OP is configured to generate a second output voltage so as to measure the current flowing through the semiconductor device. The first output voltage and the second output voltage are configured to measure an on-resistance of the semiconductor device.

In some embodiments of the present disclosure, a semiconductor system is provided. The semiconductor system includes a clamping circuit, a filter, an OP and a current sampling element. The clamping circuit is connected to a first terminal of a semiconductor device. The filter is connected to the clamping circuit. The OP is connected to the filter. The OP is configured to generate an output voltage. The current sampling element is connected to a second terminal of the semiconductor device to measure a current passing through the semiconductor device. The current and the output voltage are configured to evaluate an on-resistance of the semiconductor device.

In some embodiments of the present disclosure, a method for manufacturing and operating a semiconductor system is provided. The method includes providing a clamping circuit connected to a first terminal of a semiconductor device for protecting the semiconductor device; providing a first filter connected to the clamping circuit; providing a first operational amplifier connected to the first filter to generate a first output voltage; providing a second filter connected to a second terminal of the semiconductor device; providing a second OP connected to the second filter to generate a second output voltage; and determining an on-resistance of the semiconductor device based on the first output voltage and the second output voltage.

The semiconductor system provided by the present disclosure can filter or decrease the high-frequency electromagnetic interference caused by high-speed switching of the semiconductor device. Furthermore, compared to the clamping diode, the interference from temperature change can be avoided so as to enhance the performance of the semiconductor system for measuring the on-resistance of the semiconductor device. The signal can be amplified by the semiconductor system so as to improve the measurement for the on-resistance which may be measured by the semiconductor system. Accordingly, the on-resistance of the semiconductor device can be accurately measured or evaluated by the semiconductor system.

### BRIEF DESCRIPTION OF THE DRAWINGS

Aspects of the present disclosure are readily understood from the following detailed description when read with the accompanying figures. It should be noted that various features may not be drawn to scale. In fact, the dimensions of the various features may have arbitrarily increased or reduced for clarity of discussion.

FIG. 1A is a schematic circuit diagram of a semiconductor system according to some embodiments of the present disclosure;

FIG. 1B is a cross-sectional view of a semiconductor device according to some embodiments of the present disclosure;

FIG. 2 is another schematic circuit diagram of a semiconductor system according to some embodiments of the present disclosure;

FIG. 3 is another schematic circuit diagram of a semiconductor system according to some embodiments of the present disclosure;

FIG. 4 is another schematic circuit diagram of a semiconductor system according to some embodiments of the present disclosure;

FIGS. 5A and 5B illustrate some operations to manufacture and operate a semiconductor system according to some embodiments of the present disclosure.

### DETAILED DESCRIPTION

The following disclosure provides for many different embodiments, or examples, for implementing different features of the provided subject matter. Specific examples of components and arrangements are described below. These are, of course, merely examples and are not intended to be limiting. In the present disclosure, reference to the formation of a first feature over or on a second feature in the description that follows may include embodiments in which the first and second features are formed in direct contact, and may also include embodiments in which additional features may have formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Embodiments of the present disclosure are discussed in detail below. It should be appreciated, however, that the present disclosure provides many applicable concepts that can be embodied in a wide variety of specific contexts. The specific embodiments discussed are merely illustrative and do not limit the scope of the disclosure.

A direct band gap material, such as a group III-V compound, may include but is not limited to, for example, gallium arsenide (GaAs), indium phosphide (InP), gallium nitride (GaN), Indium gallium arsenide (InGaAs), Indium aluminum arsenide (InAlAs), and the like.

FIG. TA is a schematic circuit diagram of a semiconductor system 1 according to some embodiments of the present disclosure. As shown in FIG. TA, the semiconductor system 1 can include a semiconductor device 100, a driver 102, a clamping circuit 104, two filters 110 and 120, two operational amplifiers (OPs) 130 and 140, and a measurement resistor 150.

In some embodiments, the semiconductor device 100 can include a semiconductor layer. The semiconductor device 100 can include a group III-V semiconductor material. The semiconductor device 100 can include a group III-V dielectric material. The semiconductor device 100 can be a device under test (DUT). The semiconductor device 100 can be a DUT which may be measured by the semiconductor system 1. In some embodiments, the semiconductor device 100 can include three terminals 100a, 100b and 100c. The terminal 100a can be electrically connected to a drain electrode of the semiconductor device 100. The terminal 100b can be electrically connected to a gate electrode of the semiconductor device 100. The terminal 100c can be electrically connected to a source electrode of the semiconductor device 100.

The driver 102 can be used to drive and control the semiconductor device 100. The driver 102 is electrically connected to the terminal 100b of the semiconductor device 100. The driver 102 may include a gate driver. The signal 101 can be received by the driver 102 for regulating the semiconductor device 100. The signal 101 can include a pulse width modulation (PWM) signal.

The clamping circuit 104 can be arranged between the terminal 100a and the filter 110. The clamping circuit 104 may include, for example, a transistor. The clamping circuit 104 can be electrically connected to the terminal 100a of the semiconductor device 100 to prevent the semiconductor device 100 from interference. The signal 103 can be received by the clamping circuit 104 for operating or controlling the clamping circuit 104. The signal 103 can include a PWM signal. The signal 103 of the clamping circuit 104 can be synchronized with the signal 101 of the driver 102.

In some embodiments, the filter 110 can be arranged between the clamping circuit 104 and the OP 130. The filter 110 can be electrically connected to the clamping circuit 104. The filter 110 may include, for example, a resistor. The filter 110 may include, for example, a capacitor. The filter 110 can be used to filter or reduce high-frequency electromagnetic interference, which might be caused by high-speed switching of the semiconductor device 100. Therefore, the measurement accuracy for the semiconductor device 100 which may be measured by the semiconductor system 1 can be improved accordingly.

The OP 130 can be arranged after arranging the filter 110 and the filter 120. The OP 130 can be electrically connected to the filter 110 and the filter 120. The OP 130 can be configured as a differential OP to generate the output voltage 136. As such, a voltage drop across the measurement resistor 150 can be excluded and an on-state voltage drop across the semiconductor device 100 can be measured accurately and efficiently.

The OP 140 can be arranged after arranging the filter 120. The OP 140 can be electrically connected to the filter 120. The OP 140 can be configured to generate the output voltage 146. The output voltage 146 can be used to measure the current flowing through the semiconductor device 100. In some embodiments, the output voltages 136 and 146 can be used to evaluate or measure an on-resistance of the semiconductor device 100. The on-resistance can be used to evaluate the electrical characteristic of the semiconductor device 100 after it is turned on. The on-resistance can be used to analyze the performance or reliability of the semiconductor device 100 when operated.

In some embodiments, the filter 120 can be arranged between the OP 140 and the semiconductor device 100. The filter 120 can be arranged between the OP 140 and the measurement resistor 150. The filter 120 can be electrically connected to the semiconductor device 100, the OP 140 and the measurement resistor 150. The measurement resistor 150 can be arranged between the terminal 100c and the ground. The measurement resistor 150 can be electrically connected to the semiconductor device 100.

Furthermore, the filter 120 may include, for example, a resistor. The filter 120 may include, for example, a capacitor. The filter 120 can be used to filter or reduce high-frequency electromagnetic interference, which might be caused by high-speed switching of the semiconductor device 100. Therefore, the measurement accuracy for the semiconductor device 100 which may be measured by the semiconductor system 1 can be improved accordingly.

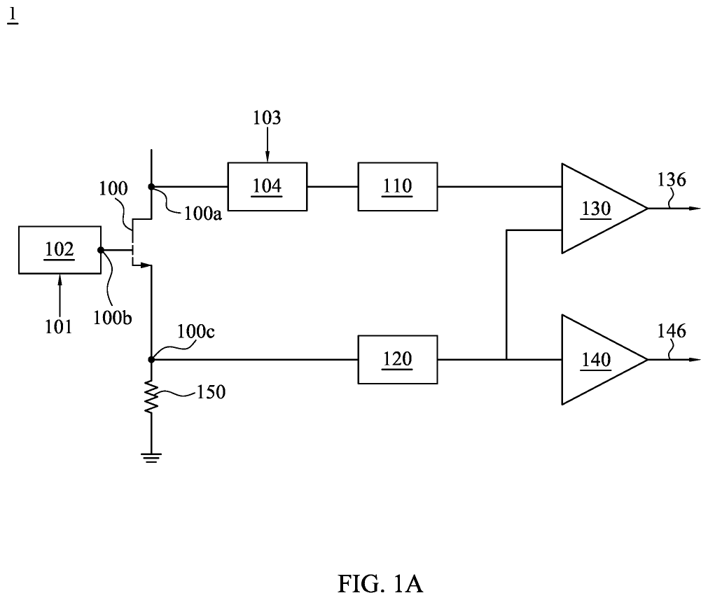

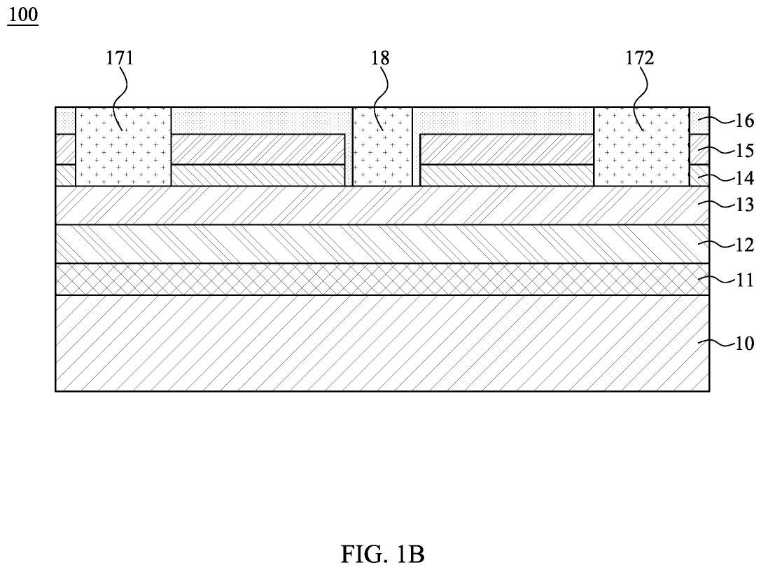

FIG. 1B is a cross-sectional view of the semiconductor device 100 according to some embodiments of the present disclosure. As shown in FIG. 1B, the semiconductor device 100 may include a substrate 10, a buffer layer 11, a semiconductor layer 12, a semiconductor layer 13, a group III-V dielectric layer 14, a passivation layer 15, a passivation layer 16, a conductive structure 171, a conductive structure 172 and a conductive structure 18.

The substrate 10 may include, for example, but is not limited to, silicon (Si), doped silicon (doped Si), silicon carbide (Sic), germanium silicide (SiGe), gallium arsenide (GaAs), or another semiconductor material. In some embodiments, the substrate 10 may include an intrinsic semiconductor material. In some embodiments, the substrate 10 may include a p-type semiconductor material. In some embodiments, the substrate 10 may include a silicon layer doped with boron (B). In some embodiments, the substrate 10 may include a silicon layer doped with gallium (Ga). In some embodiments, the substrate 10 may include an n-type semiconductor material. In some embodiments, the substrate 10 may include a silicon layer doped with arsenic (As). In some embodiments, the substrate 10 may include a silicon layer doped with phosphorus (P).

The buffer layer 11 may be disposed on the substrate 10. In some embodiments, the buffer layer 11 may include nitrides. In some embodiments, the buffer layer 11 may include, for example, but is not limited to, aluminum nitride (AlN). In some embodiments, the buffer layer 11 may include, for example, but is not limited to, aluminum gallium nitride (AlGaN). The buffer layer 11 may include a multilayer structure. The buffer layer 11 may include a superlattice layer with periodic structure of two or more materials. The buffer layer 11 may include a single layer structure.

The semiconductor layer 12 may be disposed on the buffer layer 11. The semiconductor layer 12 may include group III-V materials. The semiconductor layer 12 may be a nitride semiconductor layer. The semiconductor layer 12 may include, for example, but is not limited to, group III nitride. The semiconductor layer 12 may include, for example, but is not limited to, GaN. The semiconductor layer 12 may include, for example, but is not limited to, AlN. The semiconductor layer 12 may include, for example, but is not limited to, InN. The semiconductor layer 12 may include, for example, but is not limited to, compound InₓAl_{y}Ga_{1-x-y}N, where x+y≤1. The semiconductor layer 12 may include, for example, but is not limited to, compound Al_{y}Ga_{(1-y)}N, where y≤1.

The semiconductor layer 13 may be disposed on the semiconductor layer 12. The semiconductor layer 13 may include group III-V materials. The semiconductor layer 13 may be a nitride semiconductor layer. The semiconductor layer 13 may include, for example, but is not limited to, group III nitride. The semiconductor layer 13 may include, for example, but is not limited to, compound Al_{y}Ga_{(1-y)}N, where y≤1. The semiconductor layer 13 may include, for example, but is not limited to, GaN. The semiconductor layer 13 may include, for example, but is not limited to, AlN. The semiconductor layer 13 may include, for example, but is not limited to, InN. The semiconductor layer 13 may include, for example, but is not limited to, compound InₓAl_{y}Ga_{1-x-y}N, where x+y≤1.

A heterojunction may be formed between the semiconductor layer 13 and the semiconductor layer 12. The semiconductor layer 13 may have a band gap greater than a band gap of the semiconductor layer 12. For example, the semiconductor layer 13 may include AlGaN that may have a band gap of about 4 eV, and the semiconductor layer 12 may include GaN that may have a band gap of about 3.4 eV.

In the semiconductor device 100, the semiconductor layer 12 may be used as a channel layer. In the semiconductor device 100, the semiconductor layer 12 may be used as a channel layer disposed on the buffer layer 11. In the semiconductor device 100, the semiconductor layer 13 may be used as a barrier layer. In the semiconductor device 100, the semiconductor layer 13 may be used as a barrier layer disposed on the semiconductor layer 12.

In the semiconductor device 100, because the band gap of the semiconductor layer 12 is less than the band gap of the semiconductor layer 13, two dimensional electron gas (2DEG) may be formed in the semiconductor layer 12. In the semiconductor device 100, because the band gap of the semiconductor layer 12 is less than the band gap of the semiconductor layer 13, 2DEG may be formed in the semiconductor layer 12 and the 2DEG is close to the interface of the semiconductor layer 13 and the semiconductor layer 12. In the semiconductor device 100, because the band gap of the semiconductor layer 13 is greater than the band gap of the semiconductor layer 12, 2DEG may be formed in the semiconductor layer 12. In the semiconductor device 100, because the band gap of the semiconductor layer 13 is greater than the band gap of the semiconductor layer 12, 2DEG may be formed in the semiconductor layer 12 and the 2DEG is close to the interface of the semiconductor layer 13 and the semiconductor layer 12.

The group III-V dielectric layer 14 may be disposed on the semiconductor layer 13. The group III-V dielectric layer 14 may be in direct contact with the semiconductor layer 13. The group III-V dielectric layer 14 may separate the conductive structure 18 from the conductive structure 171. The group III-V dielectric layer 14 may separate the conductive structure 18 from the conductive structure 172. The group III-V dielectric layer 14 may include nitride. The group III-V dielectric layer 14 may include, for example, but is not limited to, AlN. The group III-V dielectric layer 14 may include, for example, but is not limited to, boron nitride (BN). The group III-V dielectric layer 14 may electrically isolate the conductive structure 18. The group III-V dielectric layer 14 may electrically isolate the conductive structure 171. The group III-V dielectric layer 14 may electrically isolate the conductive structure 172. The group III-V dielectric layer 14 may have a thickness between approximately 1 nm and approximately 10 nm. The group III-V dielectric layer 14 may have a thickness between approximately 3 nm and approximately 8 nm. The group III-V dielectric layer 14 may have a thickness of about 5 nm.

The passivation layer 15 may be disposed on the semiconductor layer 13. The passivation layer 15 may extend on the semiconductor layer 13. The passivation layer 15 may be disposed on the group III-V dielectric layer 14. The passivation layer 15 may cover the group III-V dielectric layer 14. The passivation layer 15 may extend along the group III-V dielectric layer 14. The passivation layer 15 may be in direct contact with the group III-V dielectric layer 14. The passivation layer 15 may separate the conductive structure 18 from the conductive structure 171. The passivation layer 15 may separate the conductive structure 18 from the conductive structure 172. The passivation layer 15 may include a dielectric material. The passivation layer 15 may include a non-group III-V dielectric material. The passivation layer 15 may include nitride. The passivation layer 15 may include, for example, but is not limited to, silicon nitride (Si₃N₄). The passivation layer 15 may include oxide. The passivation layer 15 may include, for example, but is not limited to, silicon oxide (SiO₂). The passivation layer 15 may electrically isolate the conductive structure 18. The passivation layer 15 may electrically isolate the conductive structure 171. The passivation layer 15 may electrically isolate the conductive structure 172. The passivation layer 15 may have a thickness between approximately 10 nm and approximately 100 nm. The passivation layer 15 may have a thickness between approximately 30 nm and approximately 70 nm. The passivation layer 15 may have a thickness of about 50 nm.

The passivation layer 16 may be disposed on the semiconductor layer 13. The passivation layer 16 may extend on the semiconductor layer 13. The passivation layer 16 may be disposed on the group III-V dielectric layer 14. The passivation layer 16 may cover the group III-V dielectric layer 14. The passivation layer 16 may cover the sidewall of the group III-V dielectric layer 14. The passivation layer 16 may extend along the group III-V dielectric layer 14. The passivation layer 16 may surround the group III-V dielectric layer 14. The passivation layer 16 may be in direct contact with the group III-V dielectric layer 14. The passivation layer 16 may be in direct contact with the sidewall of the group III-V dielectric layer 14. The passivation layer 16 may be disposed on the passivation layer 15. The passivation layer 16 may cover the passivation layer 15. The passivation layer 16 may cover the sidewall of the passivation layer 15. The passivation layer 16 may extend along the passivation layer 15. The passivation layer 16 may surround the passivation layer 15. The passivation layer 16 may be in direct contact with the passivation layer 15. The passivation layer 16 may be in direct contact with the sidewall of the passivation layer 15. The passivation layer 16 may be in direct contact with the conductive structure 18. The passivation layer 16 may separate the conductive structure 18 from the conductive structure 171. The passivation layer 16 may separate the conductive structure 18 from the conductive structure 172. The passivation layer 16 may separate the conductive structure 18 from the group III-V dielectric layer 14. The passivation layer 16 may separate the conductive structure 18 from the passivation layer 15. The passivation layer 16 may include a dielectric material. The passivation layer 16 may include a non-group III-V dielectric material. The passivation layer 16 may include nitride. The passivation layer 16 may include, for example, but is not limited to, Si₃N₄. The passivation layer 16 may include oxide. The passivation layer 16 may include, for example, but is not limited to, SiO₂. The passivation layer 16 may electrically isolate the conductive structure 18. The passivation layer 16 may electrically isolate the conductive structure 171. The passivation layer 16 may electrically isolate the conductive structure 172. The passivation layer 16 may have a thickness between approximately 1 nm and approximately 100 nm. The passivation layer 16 may have a thickness between approximately 30 nm and approximately 70 nm. The passivation layer 16 may have a thickness of about 50 nm.

The passivation layer 16 may have a different material from that of the group III-V dielectric layer 14. The passivation layer 16 may have a different material from that of the passivation layer 15. The passivation layer 16 may have a material identical to that of the passivation layer 15. As the passivation layer 16 and the passivation layer 15 have the same material, the passivation layer 16 and the passivation layer 15 may be regarded as one single layer. For example, the group III-V dielectric layer 14 may include AlN, the passivation layer 15 may include SiO₂ and the passivation layer 16 may include Si₃N₄. For example, the group III-V dielectric layer 14 may include AlN, the passivation layer 15 may include Si₃N₄ and the passivation layer 16 may include Si₃N₄. For example, the group III-V dielectric layer 14 may include AlN, the passivation layer 15 may include SiO₂ and the passivation layer 16 may include SiO₂. For example, the group III-V dielectric layer 14 may include BN, the passivation layer 15 may include SiO₂ and the passivation layer 16 may include Si₃N₄. For example, the group III-V dielectric layer 14 may include BN, the passivation layer 15 may include Si₃N₄ and the passivation layer 16 may include Si₃N₄. For example, the group III-V dielectric layer 14 may include BN, the passivation layer 15 may include SiO₂ and the passivation layer 16 may include SiO₂.

The conductive structure 171 may be disposed on the semiconductor layer 13. The conductive structure 171 may contact the semiconductor layer 13. The conductive structure 171 may be electrically connected to the semiconductor layer 12. The conductive structure 171 may be electrically connected to the semiconductor layer 12 through the semiconductor layer 13. The conductive structure 171 may be surrounded by the group III-V dielectric layer 14. The conductive structure 171 may be surrounded by the passivation layer 15. The conductive structure 171 may be surrounded by the passivation layer 16. The conductive structure 171 may include a conductive material. The conductive structure 171 may include a metal. The conductive structure 171 may include, for example, but is not limited to, Al. The conductive structure 171 may include, for example, but is not limited to, Ti. The conductive structure 171 may include a metal compound. The conductive structure 171 may include, for example, but is not limited to, titanium nitride (TiN).

The conductive structure 172 may be disposed on the semiconductor layer 13. The conductive structure 172 may contact the semiconductor layer 13. The conductive structure 172 may be electrically connected to the semiconductor layer 12. The conductive structure 172 may be electrically connected to the semiconductor layer 12 through the semiconductor layer 13. The conductive structure 172 may be surrounded by the group III-V dielectric layer 14. The conductive structure 172 may be surrounded by the passivation layer 15. The conductive structure 172 may be surrounded by the passivation layer 16. The conductive structure 172 may include a conductive material. The conductive structure 172 may include a metal. The conductive structure 172 may include, for example, but is not limited to, Al. The conductive structure 172 may include, for example, but is not limited to, Ti. The conductive structure 172 may include a metal compound. The conductive structure 172 may include, for example, but is not limited to, AlN. The conductive structure 172 may include, for example, but is not limited to, TiN.

In the semiconductor device 100, the conductive structure 171 may be used as, for example, but is not limited to, a source electrode. In the semiconductor device 100, the conductive structure 171 may be used as, for example, but is not limited to, a drain electrode.

In the semiconductor device 100, the conductive structure 172 may be used as, for example, but is not limited to, a drain electrode. In the semiconductor device 100, the conductive structure 172 may be used as, for example, but is not limited to, a source electrode.

The conductive structure 18 may be disposed on the semiconductor layer 13. The conductive structure 18 may be in direct contact with the semiconductor layer 13. The conductive structure 18 may be surrounded by the passivation layer 16. The conductive structure 18 may be separated from the group III-V dielectric layer 14. The conductive structure 18 may be separated from the group III-V dielectric layer 14 by the passivation layer 16. The conductive structure 18 may include a metal. The conductive structure 18 may include, for example, but is not limited to, gold (Au), platinum (Pt), titanium (Ti), palladium (Pd), nickel (Ni), or tungsten (W). The conductive structure 18 may include a metal compound. The conductive structure 18 may include, for example, but is not limited to, TiN.

In the semiconductor device 100, the conductive structure 18 may be used as a gate electrode. In the semiconductor device 100, the conductive structure 18 may be configured to control the 2DEG in the semiconductor layer 12. In the semiconductor device 100, a voltage may be applied to the conductive structure 18 to control the 2DEG in the semiconductor layer 12. In the semiconductor device 100, a voltage may be applied to the conductive structure 18 to control the 2DEG in the semiconductor layer 12 and below the conductive structure 18. In the semiconductor device 100, a voltage may be applied to the conductive structure 18 to control the connection or disconnection between the conductive structure 171 and the conductive structure 172.

It should be noted that, the conductive structure 171 may be used as a source electrode of the semiconductor device 100, the conductive structure 172 may be used as a drain electrode of the semiconductor device 100, and the conductive structure 18 may be used as a gate electrode of the semiconductor device 100. However, the conductive structure 171, the conductive structure 172, and the conductive structure 18 may be disposed differently in other embodiments of the disclosure according to design requirements. The semiconductor device 100 may be preset to be in an OFF state when the conductive structure 18 is in a zero bias state. Such a device can be referred to as an enhancement-mode device. The semiconductor device 100 may be preset to be in an ON state when the conductive structure 18 is in a zero bias state. Such a device can be referred to as a depletion-mode device.

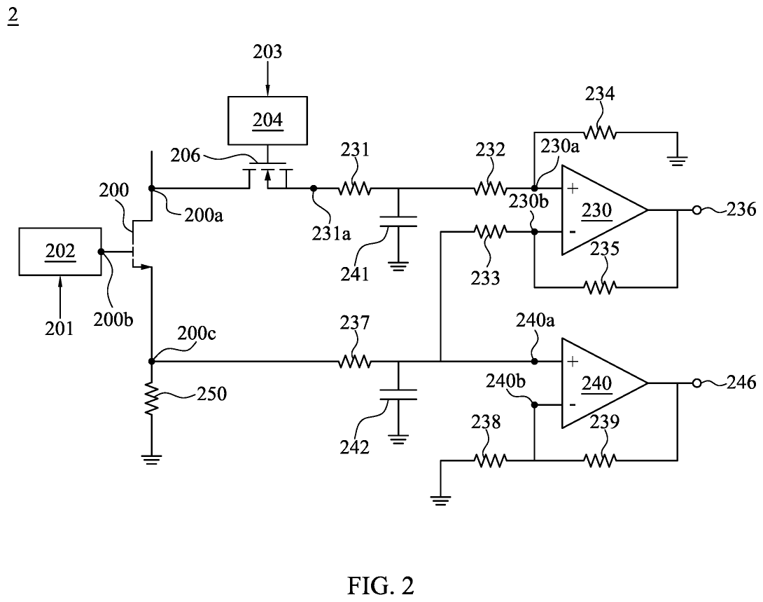

FIG. 2 is another schematic circuit diagram of a semiconductor system 2 according to some embodiments of the present disclosure. The semiconductor system 2 of FIG. 2 is similar to the semiconductor system 1 of FIG. 1A, except for the differences described as follows.

As shown in FIG. 2, the semiconductor system 2 can include a semiconductor device 200, a driver 202, a driver 204, a clamping transistor 206, two OPs 230 and 240, a measurement resistor 250, two capacitors 241 and 242, and a plurality of resistors 231, 232, 233, 234, 235, 237, 238 and 239.

The clamping transistor 206 can be arranged between the driver 204, the terminal 231a, and the terminal 200a of the semiconductor device 200. The driver 204 is electrically connected to a gate electrode of the clamping transistor 206. The driver 204 can receive the signal 203 for operating or controlling the clamping transistor 206. The drain electrode of the clamping transistor 206 can be electrically connected to the semiconductor device 200 through the terminal 200a. The source electrode of the clamping transistor 206 can be electrically connected to the resistor 231 through the terminal 231a.

The signal 201 can be received by the driver 202 for regulating the semiconductor device 200. The signal 201 can include a PWM signal. The signal 203 can be received by the driver 204 for operating or controlling the clamping transistor 206. The signal 203 can include a PWM signal. The signal 203 of the clamping transistor 206 can be synchronized with the signal 201 of the driver 202.

In some embodiments, a time offset or a time dead zone, such as 0.1 microseconds to 1 microseconds, can be provided between the two signals 201 and 203. By utilizing the time dead zone, the clamping transistor 206 can be turned on after the semiconductor device 200 is turned on. The clamping transistor 206 can be turned off before the semiconductor device 200 is turned off. As a result, the operation and the reliability of the clamping transistor 206 can be improved.

Because the clamping transistor 206 can be turned on after the semiconductor device 200 is turned on, a portion of the current passing through the semiconductor device 200 can be transmitted to the body diode of the semiconductor device 200, the resistors 231, 232, 234 and the ground. The current passing through the body diode can be much smaller than the current passing through the semiconductor device 200. Therefore, the on-resistance of the semiconductor device 200 can be expressed by:

$$Vm = Id \times Rdson \qquad ( 1 )$$

Vm is the voltage at the terminal 231a. Id is the current passing through the semiconductor device 200. Rdson is the on-resistance of the semiconductor device 200.

In addition, the clamping transistor 206 can be used to block the high voltage at the drain electrode of the semiconductor device 200 when the semiconductor device 200 is turned off Therefore, the rest of this semiconductor system 2 can be protected by the clamping transistor 206. In addition, compared to the clamping diode, the interference from temperature change can be avoided so as to enhance the performance of the semiconductor system 2 for measuring the on-resistance of the semiconductor device 200.

In some embodiments, the resistor 231 can be arranged between the terminal 231a and the capacitor 241. The resistor 231 can be arranged between the terminal 231a and the resistor 232. The resistor 231 and the capacitor 241 can be electrically connected in series. The resistor 231 and the capacitor 241 can correspond to the filter 110 of FIG. 1A. The resistor 231 and the capacitor 241 can form a low-pass filter. The bandwidth for the low-pass filter can be described as follows:

$$f 1 = \frac{1}{2 π \times \sqrt{R 1 \times C 1}} \qquad ( 2 )$$

Note that f1 is a filtering frequency of the low-pass filter including the resistor 231 and the capacitor 241. R1 is the resistance of the resistor 231. C1 is the capacitance of the capacitor 241.

In some embodiments, the resistor 237 can be arranged between the terminal 200c and the capacitor 242. The resistor 237 and the capacitor 242 can be electrically connected in series. The resistor 237 and the capacitor 242 can correspond to the filter 120 of FIG. 1A. The resistor 237 and the capacitor 242 can form a low-pass filter. The bandwidth for the low-pass filter can be described as follows:

$$f 2 = \frac{1}{2 π \times \sqrt{R 2 \times C 2}} \qquad ( 3 )$$

Note that f2 is a filtering frequency of the low-pass filter including the resistor 237 and the capacitor 242. R2 is the resistance of the resistor 237. C2 is the capacitance of the capacitor 242.

In some embodiments, the resistor 231, the capacitor 241, the resistor 237 and the capacitor 242 can be used to filter or reduce high-frequency electromagnetic interference, which might be caused by high-speed switching of the semiconductor device 200. Therefore, the on-resistance of the semiconductor device 200 can be accurately measured or evaluated by the semiconductor system 2.

The resistor 232 can be provided between the resistor 231 and the terminal 230a of the OP 230. The resistor 232 can be provided between the capacitor 241 and the terminal 230a of the OP 230. The terminal 230a can be the non-inverting input of the OP 230. The resistor 234 can be arranged between the resistor 232 and the ground. The resistor 234 can be arranged between the terminal 230a and the ground.

The resistor 233 can be provided between the resistor 237 and the terminal 230b of the OP 230. The resistor 233 can be provided between the capacitor 242 and the terminal 230b of the OP 230. The terminal 230b can be the inverting input of the OP 230. The resistor 235 can be arranged between the resistor 233 and the output 236 of the OP 230. The resistor 235 can be arranged between the terminal 230b and the output 236.

In some embodiments, the resistance of the resistor 232 is substantially identical to the resistance of the resistor 233. The resistance of the resistor 234 is substantially identical to the resistance of the resistor 235. Based on the foregoing, the voltage gain for the OP 230 can be described as follows:

$$Avdson = \frac{R 4}{R 3} \qquad ( 4 )$$

Note that Avdson is the voltage gain of the OP 230. R4 is the resistance of the resistor 234 and the resistor 235. R3 is the resistance of the resistor 232 and the resistor 233. The voltage gain Avdson of the OP 230 is substantially equal to a resistance ratio of the resistor 234 to the resistor 232. Therefore, the signal can be amplified by the OP 230 so as to improve the measurement for the on-resistance which may be measured by the semiconductor system 2.

In addition, the voltage Vdson at the output 236 of the OP 230 can be described as follows:

$$Adson = Avdson \times Id \times Rdson \qquad ( 5 )$$

In some embodiments, as illustrated in FIG. 2, the terminal 240a of the OP 240 can be a non-inverting input. The terminal 240a can be electrically connected to the resistor 233. The terminal 240a can be electrically connected to the resistor 237. The terminal 240a can be electrically connected to the capacitor 242.

In some embodiments, the resistor 238 can be arranged between the terminal 240b and the ground. The resistor 238 can be arranged between the resistor 239 and the ground. In some embodiments, the resistor 239 can be arranged between the terminal 240b and the output 246 of the OP 240. The terminal 240b can be the inverting input of the OP 240. The resistor 239 can be arranged between the resistor 238 and the output 246 of the OP 240.

Based on the foregoing, the voltage gain for the OP 240 can be described as follows:

$$Avcs = 1 + \frac{R 6}{R 5} \qquad ( 6 )$$

Note that Avcs is the voltage gain of the OP 240. R5 is the resistance of the resistor 238. R6 is the resistance of the resistor 239. The voltage gain Avcs of the OP 240 is substantially equal to a resistance ratio of the resistor 239 to the resistor 238 plus 1. Therefore, the signal can be amplified by the OP 240 so as to improve the measurement for the on-resistance which may be measured by the semiconductor system 2.

In some embodiments, as illustrated in FIG. 2, the measurement resistor 250 can be arranged between the terminal 200c of the semiconductor device 200 and the ground. The measurement resistor 250 can be arranged between the resistor 237 and the ground. The measurement resistor 250 can be used to sample or evaluate the current of the semiconductor device 200. Accordingly, the relationship between the voltage Vcs and the current Id can be described as follows:

$$Vcs = Avcs \times Id \times Rsh \qquad ( 7 )$$

Note that Rsh is the resistance of the measurement resistor 250. Vcs is the voltage at the output 246 of the OP 240.

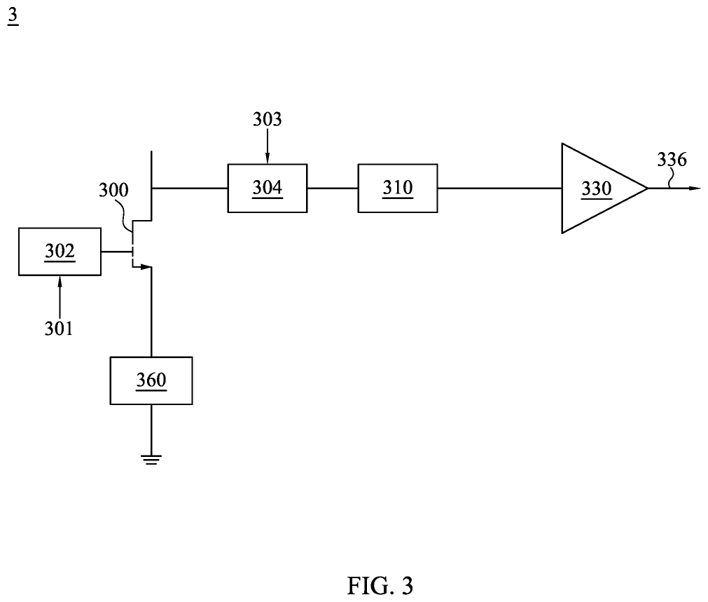

FIG. 3 is another schematic circuit diagram of a semiconductor system 3 according to some embodiments of the present disclosure. The semiconductor system 3 of FIG. 3 can be similar to the semiconductor system 1 of FIG. 1A, except for the differences described as follows.

As shown in FIG. 3, the semiconductor system 3 can include a semiconductor device 300, a driver 302, a clamping circuit 304, a filter 310, an OP 330 and a current sampling element 360. In some embodiments, the OP 330 can be electrically connected to the filter 310. The OP 330 can be configured to generate an output voltage 336.

In some embodiments, the current sampling element 360 can be electrically connected to a source electrode of the semiconductor device 300 to measure a current passing through the semiconductor device 300. The current sampling element 360 can include a current probe. The current of the semiconductor device 300 and the output voltage 336 are configured to evaluate the on-resistance of the semiconductor device 300.

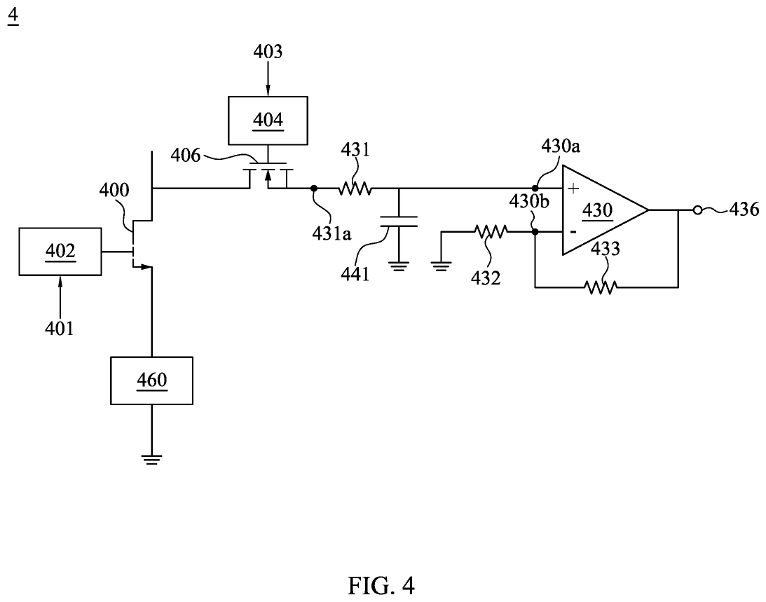

FIG. 4 is another schematic circuit diagram of the semiconductor system 4 according to some embodiments of the present disclosure. The semiconductor system 4 of FIG. 4 can be similar to the semiconductor system 3 of FIG. 3, except for the differences described as follows.

As shown in FIG. 4, the semiconductor system 4 can include a semiconductor device 400, a driver 402, a driver 404, a clamping transistor 406, an OP 430, a current sampling element 460, a capacitor 441, and a plurality of resistors 431, 432 and 433.

In some embodiments, the resistor 431 can be arranged between the terminal 431a and the capacitor 441. The resistor 431 can be arranged between the terminal 431a and the terminal 430a of the OP 430. The terminal 430a can be the non-inverting input of the OP 430. The resistor 431 and the capacitor 441 can be electrically connected in series. The resistor 431 and the capacitor 441 can correspond to the filter 310 of FIG. 3. The resistor 431 and the capacitor 441 can form a low-pass filter. The bandwidth for the low-pass filter can be described as follows:

$$f 3 = \frac{1}{2 π \times \sqrt{R 7 \times C 3}} \qquad ( 8 )$$

Note that f3 is a filtering frequency of the low-pass filter including the resistor 431 and the capacitor 441. R7 is the resistance of the resistor 431. C3 is the capacitance of the capacitor 441.

In addition, as shown in FIG. 4, the resistor 432 can be arranged between the terminal 430b and the ground. The terminal 430b can be the inverting input of the OP 430. The resistor 432 can be arranged between the resistor 433 and the ground. The resistor 433 can be arranged between the resistor 432 and the output 436 of the OP 430.

Based on the foregoing, the voltage gain for the OP 430 can be described as follows:

$${Avdson}^{′} = 1 + \frac{R 9}{R 8} \qquad ( 9 )$$

Note that R9 is the resistance of the resistor 433. R8 is the resistance of the resistor 432. The voltage gain for the OP 430 can include a current gain. In some embodiments, the voltage Vdson′ of the output 436 of the OP 430 can be described as follows:

$${Vdson}^{′} = {Avdson}^{′} \times {Id}^{′} \times {Rdson}^{′} \qquad ( 10 )$$

Note that Vdson′ is the voltage at the output 436 of the OP 430. Id′ is the current passing through the semiconductor device 400. Rdson′ is the on-resistance of the semiconductor device 400.

In addition, the sensing current Ics passes through the semiconductor device 400. The sensing current Ics can be detected by the current sampling element 460 can be described as follows:

$$Ics = {Id}^{′} \qquad ( 11 )$$

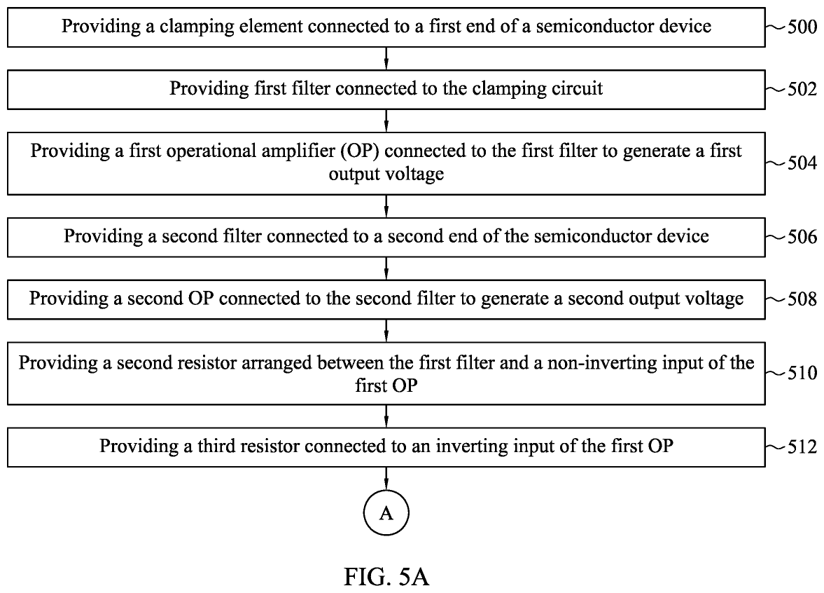

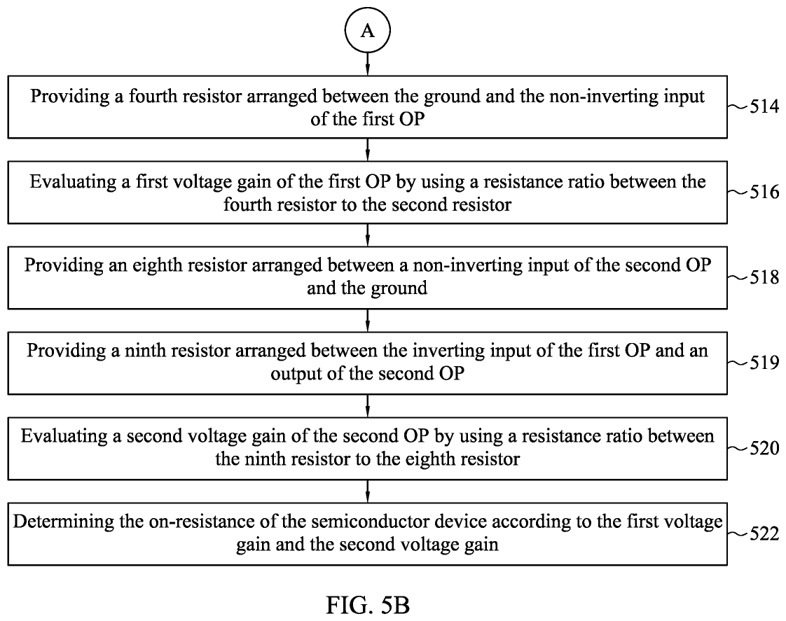

FIGS. 5A and 5B illustrate some operations to manufacture and operate a semiconductor system according to some embodiments of the present disclosure. In operation 500, a clamping element can be provided for connecting to a first end of a semiconductor device. In operation 502, a first filter connected to the clamping circuit can be provided. In operation 504, a first OP connected to the first filter can be provided to generate a first output voltage.

Moreover, in operation 506, a second filter connected to a second end of the semiconductor device can be provided. In operation 508, a second OP connected to the second filter can be provided to generate a second output voltage. In operation 510, a second resistor arranged between the first filter and a non-inverting input of the first OP can be provided. In operation 512, a third resistor connected to an inverting input of the first OP can be provided. In operation 514, a fourth resistor arranged between the ground and the non-inverting input of the first OP can be provided.

In operation 516, a first voltage gain of the first OP can be evaluated by using a resistance ratio between the fourth resistor to the second resistor. In operation 518, an eighth resistor arranged between a non-inverting input of the second OP and the ground can be provided. In operation 519, a ninth resistor arranged between the inverting input of the first OP and an output of the second OP can be provided. In operation 520, a second voltage gain of the second OP can be evaluated by using a resistance ratio between the ninth resistor to the eighth resistor. In operation 522, the on-resistance of the semiconductor device can be determined according to the first voltage gain and the second voltage gain.

While disclosed methods or operations are illustrated and described below as a series of acts or events, it will be appreciated that the illustrated ordering of such acts or events are not to be interpreted in a limiting sense. For example, some operations may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

As used herein, spatially relative terms, such as “beneath,” “below,” “lower,” “above,” “upper,” “higher,” “left,” “right” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As used herein, the terms “approximately,” “substantially,” “substantial” and “about” are used to describe and account for small variations. When used in conduction with an event or circumstance, the terms can refer to instances in which the event of circumstance occurs precisely as well as instances in which the event or circumstance occurs to a close approximation. As used herein with respect to a given value or range, the term “about” generally means within ±10%, ±5%, ±1%, or ±0.5% of the given value or range. Ranges can be expressed herein as from one endpoint to another endpoint or between two endpoints. All ranges disclosed herein are inclusive of the endpoints, unless specified otherwise. The term “substantially coplanar” can refer to two surfaces within micrometers (μm) of lying along a same plane, such as within 10 μm, within 5 μm, within 1 μm, or within 0.5 μm of lying along the same plane. When referring to numerical values or characteristics as “substantially” the same, the term can refer to the values lying within ±10%, ±5%, ±1%, or ±0.5% of an average of the values.

Several embodiments of the disclosure and features of details are briefly described above. The embodiments described in the disclosure may be easily used as a basis for designing or modifying other processes and structures for realizing the same or similar objectives and/or obtaining the same or similar advantages introduced in the embodiments of the disclosure. Such equivalent constructions do not depart from the spirit and scope of the disclosure, and various variations, replacements, and modifications can be made without departing from the spirit and scope of the disclosure.

1. A semiconductor system, comprising:
a clamping circuit, connected to a first terminal of a semiconductor device to prevent the semiconductor device from interference;
a first filter, connected to the clamping circuit;
a first operational amplifier (OP), connected to the first filter, wherein the first OP is configured as a differential OP to generate a first output voltage, so that a voltage drop across a measurement resistor is excluded and an on-state voltage drop across the semiconductor device is measured;
a second filter, connected to a second terminal of the semiconductor device; and
a second OP, connected to the second filter, wherein the second OP is configured to generate a second output voltage so as to measure a current flowing through the semiconductor device, and the first output voltage and the second output voltage are configured to measure an on-resistance of the semiconductor device.

2. The semiconductor system of claim 1, wherein the semiconductor device comprises:
a substrate;
a first nitride semiconductor layer on the substrate; and
a second nitride semiconductor layer on the first nitride semiconductor layer, wherein a band gap of the second nitride semiconductor layer is greater than that of the first nitride semiconductor layer.

3. The semiconductor system of claim 2, wherein a drain electrode, a source electrode, and a gate electrode of the semiconductor device are formed on the second nitride semiconductor layer.

4. The semiconductor system of claim 3, wherein the first terminal is connected with the drain electrode, and the second terminal is connected with the source electrode.

5. The semiconductor system of claim 1, wherein the clamping circuit comprises a clamping transistor.

6. The semiconductor system of claim 5, wherein a gate of the clamping transistor is electrically connected to a gate driver, and a drain electrode of the clamping transistor is electrically connected to the first terminal of the semiconductor device.

7. The semiconductor system of claim 6, wherein the clamping circuit is turned on after the semiconductor device is turned on, and the clamping circuit is turned off before the semiconductor device is turned off.

8. The semiconductor system of claim 6, wherein the first filter is a low-pass filter, comprising:
a first resistor; and
a first capacitor, arranged in series with the first resistor.

9. The semiconductor system of claim 8, wherein the first resistor is electrically connected to a source of the clamping transistor, and the first capacitor is electrically connected to a ground.

10. The semiconductor system of claim 9, further comprising:
a second resistor, arranged between the first filter and a first terminal of the first OP;
a third resistor, connected between the second filter and a second terminal of the first OP;
a fourth resistor, arranged between the ground and the first terminal of the first OP; and
a fifth resistor, arranged between the second terminal of the first OP and an output of the first OP.

11. The semiconductor system of claim 10, wherein a first voltage gain of the first OP is substantially equal to a resistance ratio of the fourth resistor to the second resistor.

12. The semiconductor system of claim 11, wherein the measurement resistor is arranged between the semiconductor device and the ground to measure the current flowing through the semiconductor device.

13. The semiconductor system of claim 12, wherein the second filter is a low-pass filter, comprising:
a seventh resistor electrically connected to the measurement resistor; and
a second capacitor, arranged in series with the seventh resistor.

14. The semiconductor system of claim 13, further comprising:
an eighth resistor, arranged between a first terminal of the second OP and the ground; and
a ninth resistor, arranged between the first terminal of the second OP and an output of the second OP.

15. The semiconductor system of claim 14, wherein a second voltage gain of the second OP is determined according to a resistance ratio of the ninth resistor to the eighth resistor, and the on-resistance of the semiconductor device is determined according to the first output voltage, the first voltage gain, the second output voltage, and the second voltage gain.

16. A method for manufacturing and operating a semiconductor system, comprising:
providing a clamping circuit, connected to a first terminal of a semiconductor device for protecting the semiconductor device;
providing a first filter, connected to the clamping circuit;
providing a first operational amplifier (OP), connected to the first filter to generate a first output voltage;
providing a second filter, connected to a second terminal of the semiconductor device;
providing a second OP, connected to the second filter to generate a second output voltage; and
determining an on-resistance of the semiconductor device based on the first output voltage and the second output voltage.

17. The method according of claim 16, further comprising:
providing a clamping transistor.

18. The method of claim 16, further comprising:
turning on the clamping circuit after turning on the semiconductor device; and
turning off the clamping circuit before turning off the semiconductor device.

19. The method of claim 16, further comprising:
providing a second resistor, arranged between the first filter and a first terminal of the first OP;
providing a third resistor, connected between the second filter and a second terminal of the first OP;
providing a fourth resistor, arranged between a ground and the first terminal of the first OP; and
evaluating a first voltage gain of the first OP by using a resistance ratio between the fourth resistor to the second resistor.

20. The method of claim 19, further comprising:
providing an eighth resistor, arranged between a first terminal of the second OP and the ground;
providing a ninth resistor, arranged between the first terminal of the first OP and an output of the second OP; and
evaluating a second voltage gain of the second OP by using a resistance ratio between the ninth resistor to the eighth resistor, wherein the on-resistance of the semiconductor device is determined according to the first output voltage, the first voltage gain, the second output voltage, and the second voltage gain.

21. A semiconductor system, comprising:
a clamping circuit, connected to a first terminal of a semiconductor device;
a filter, connected to the clamping circuit;
an operational amplifier (OP), connected to the filter, wherein the OP is configured to generate an output voltage; and
a current sampling element, connected to a second terminal of the semiconductor device to measure a current passing through the semiconductor device, wherein the current and the output voltage are configured to evaluate an on-resistance of the semiconductor device.

22. The semiconductor system of claim 21, wherein the semiconductor device comprises:
a substrate;
a first nitride semiconductor layer on the substrate; and
a second nitride semiconductor layer on the first nitride semiconductor layer, wherein a band gap of the second nitride semiconductor layer is greater than that of the first nitride semiconductor layer.

23. The semiconductor system of claim 21, wherein the filter comprises:
a first resistor, electrically connected to the clamping circuit; and
a first capacitor, arranged in series with the first resistor and electrically connected to a ground.

24. The semiconductor system of claim 23, further comprising:
a second resistor, arranged between a first terminal of the OP and the ground; and
a third resistor, arranged between the first terminal of the OP and an output of the OP.

25. The semiconductor system of claim 24, wherein a voltage gain of the OP corresponds to a resistance ratio of the third resistor to the second resistor, and the on-resistance of the semiconductor device is determined according to the output voltage, the voltage gain, and the current.
